(19) United States
(12) Patent Application Publication
(10) Pub. No.: US 2013/0335896 A1
(43) Pub. Date: Dec. 19, 2013

(54) CHIP CARD HOLDER WITH PROTECTIVE COVER FOR PORTABLE ELECTRONIC DEVICES

(71) Applicants: SHENZHEN FUTAIHONG PRECISION INDUSTRY CO., LTD., Shenzhen (CN); FIH (HONG KONG) LIMITED, Kowloon (HK)

(72) Inventor: YAN-LING GAO, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/862,873

(22) Filed: Apr. 15, 2013

(30) Foreign Application Priority Data
Jun. 19, 2012 (CN) 201220288094.3

(51) Int. Cl. H05K 7/14; H05K 5/03

(52) U.S. Cl. CPC H05K 7/1461; H05K 5/03
USPC 361/679.01

(57) ABSTRACT

A chip card holder includes a housing defining a hole, a receiving frame, an ejecting member, a tray, an elastic member, and a protective cover. The receiving frame is mounted on the housing. The ejecting member is positioned at one end of the receiving frame. The tray is slidably received in the receiving frame and is abutted by the ejecting member. The elastic member is positioned between the tray and the protective cover. The protective cover is slidably connected to the tray and covers the hole. After the protective cover is slid along the housing and is unlocked from the housing, the ejecting member ejects the tray from the housing.

### BACKGROUND

1. Technical Field

The present disclosure relates to chip card holders, and particularly to a chip card holder with a protective cover for portable electronic devices.

2. Description of Related Art

With the development of wireless communication and information processing technologies, portable electronic devices such as mobile phones are now widely used. Surface contact cards are necessary elements in portable electronic devices.

A conventional chip card holder includes a protective cover, which is directly exposed from housings of the portable electronic device. The exposed cover defines a hole for convenient insertion and removal of the surface contact card with a tool. However, the hole in the portable electronic device affects the appearance. In addition, the tool is easily lost, and the operation of removing the protective cover is troublesome.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the exemplary chip card holder and portable electronic device using the chip card holders. Moreover, in the drawings like reference numerals designate corresponding parts throughout the several views. Wherever possible, the same reference numbers are used throughout the drawings to refer to the same or like elements of an embodiment.

FIG. 1 is an exploded view of one embodiment of a chip card holder used in a portable electronic device.

FIG. 2 is similar to FIG. 1, but viewed from another aspect.

FIG. 3 is an assembled view of the chip card holder, showing a protective cover in a closed state.

FIG. 4 is a cross sectional view of the chip card holder of FIG. 3 taken along line IV-IV.

FIG. 5 is similar to FIG. 4, but showing the protective cover in an unlocked state.

FIG. 6 is similar to FIG. 4, but showing the protective cover extending out of the housing.

### DETAILED DESCRIPTION

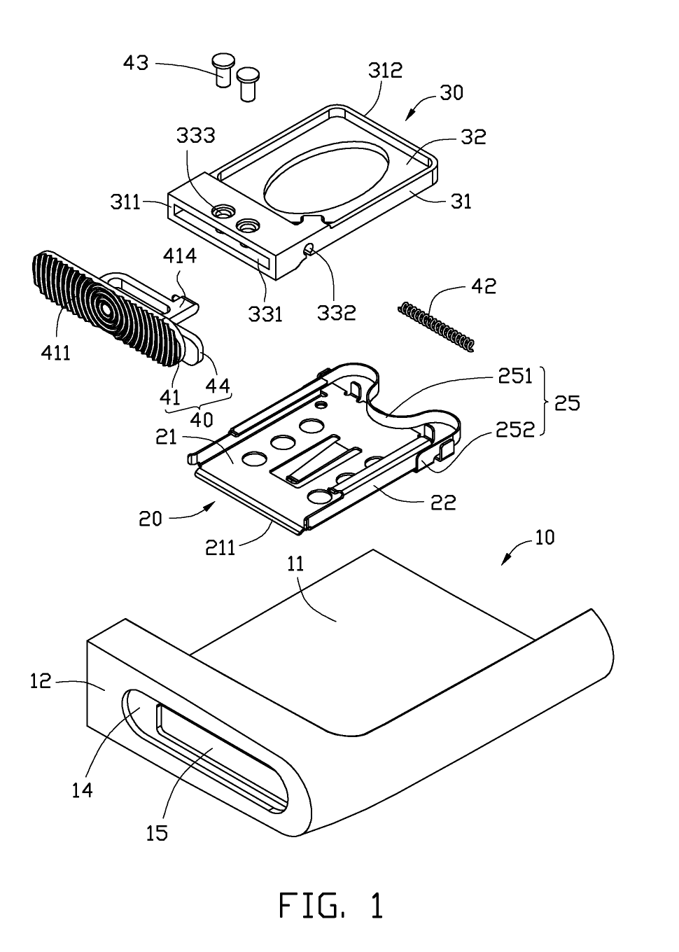

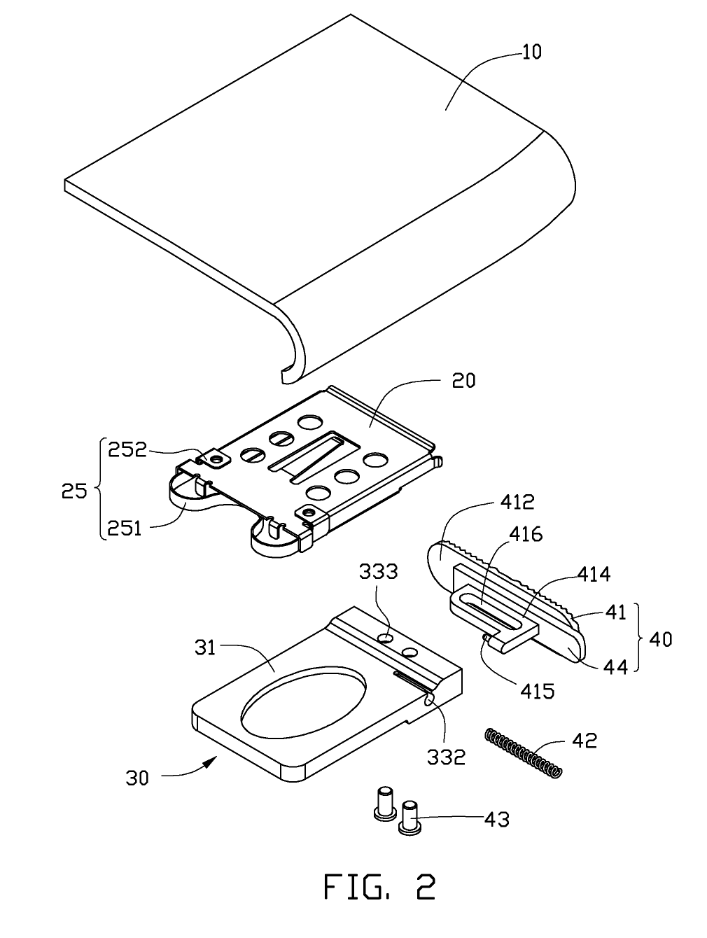

Referring to FIGS. 1 to 3, shown is an exemplary embodiment of a chip card holder which can be used in a portable electronic device, such as a cellular phone or any electronic device where a chip card is required. The portable electronic device includes a housing 10. The chip card holder is assembled in the housing 10. A chip card (not shown) can be selectively placed in the chip card holder. The chip card may be a subscriber identity module (SIM) card or a flash card.

The chip card holder includes a receiving frame 20, an ejecting member 25, a tray 30, a protective cover 40, an elastic member 42, and two fasteners 43.

The housing 10 may be a portion of the portable electronic device or a separate element fixed to the portable electronic device. In this exemplary embodiment, the housing 10 is a top portion or a bottom portion of the portable electronic device. The housing 10 includes a main body 11 and an end wall 12 integrated with the main body 11. The end wall 12 defines a first hole 14 in the exterior surface of the end wall 12 and a second hole 15 is formed in the interior surface of the end wall 12 partially aligned with the first hole 14. Opposite ends of the first hole 14 are not aligned with those of the second hole 15, thereby a stopper portion 16 is formed between the first hole 14 and the second hole 15. The chip card holder can be received inside of the housing 10 through the first hole 14 and the second hole 15, and is supported by the main body 11.

The receiving frame 20 is secured in the main body 11 adjacent to and aligned with the first hole 14 and the second hole 15. The receiving frame 20 includes a frame body 21 and two opposite flanges 22, thereby cooperatively defining a receiving cavity communicating with the second hole 15 and the first hole 14 for receiving the tray 30. An entrance 211 is defined at one end of the frame body 21 to allow the tray 30 to be inserted into the receiving cavity therethrough.

The ejecting member 25 is mounted on another end of the receiving frame 20 configured for abutting against the tray 30. In this exemplary embodiment, the ejecting member 25 is made of an elastic sheet, and includes an elastic body 251 and two mounting portions 252. The elastic body 251 is substantially configured in a W-shape for providing an elastic force for ejecting the tray 30 from the receiving frame 20. Each mounting portion 252 is located at one end of the elastic body 251, and is configured for being mounted on the frame body 21.

The tray 30 includes a tray body 31 configured for being slidably received in the receiving frame 20. The tray body 31 defines a receiving groove 32 in one surface for receiving the chip card. The tray body 31 includes a mounting portion 311 and a distal end 312 opposite to each other. The mounting portion 311 defines a slot 331, a cutout 332, and two fastener holes 333. The slot 331 is defined at a middle area of the mounting portion 311, and communicates with one end of the mounting portion 311. The two fastener holes 333 communicate with the opposite surface of the mounting portion 311. The cutout 332 is defined at another surface of the mounting portion 311 opposite to the receiving groove 32. The cutout 332 communicates with the slot 331, and is configured for receiving the elastic member 42.

The protective cover 40 is configured for slidably engaging in the first hole 14 and the second hole 15. The protective cover 40 includes a first plate portion 41 and a second plate portion 44. The first plate portion 41 is shorter than the first hole 14 to allow the first plate portion 41 to slide in the first hole 14. The first plate portion 41 includes a first surface 411 and a second surface 412 opposite to each other. The first surface 411 has a plurality of ribs to provide a gripping surface for convenient manipulation of the protective cover 40. The second plate portion 44 extends from the second surface 412, and is offset from the first plate portion 41 for engaging with the stopper portion 16. The second plate portion 44 is shorter than the second hole 15 to allow the second plate portion 44 to slide in the second hole 15. An extending block 414 perpendicularly extends from the second plate portion 44. A guiding groove 416 is defined in the extending block 414. A post 415 projects from one end of the extending block 414. When the protective cover 40 is partially received in the slot 331 of the tray 30, the fastener holes 333 are aligned with the guiding groove 416, and the post 415 is aligned with the cutout 332.

In this exemplary embodiment, the elastic member 42 is a helical compression spring. The elastic member 42 is configured for being received in the cutout 322, and is fitted around the post 415. The two fasteners 43 can be any suitable fastener engageable in the fastener holes 333 of the tray 30 such as through friction fit or threaded engagement.

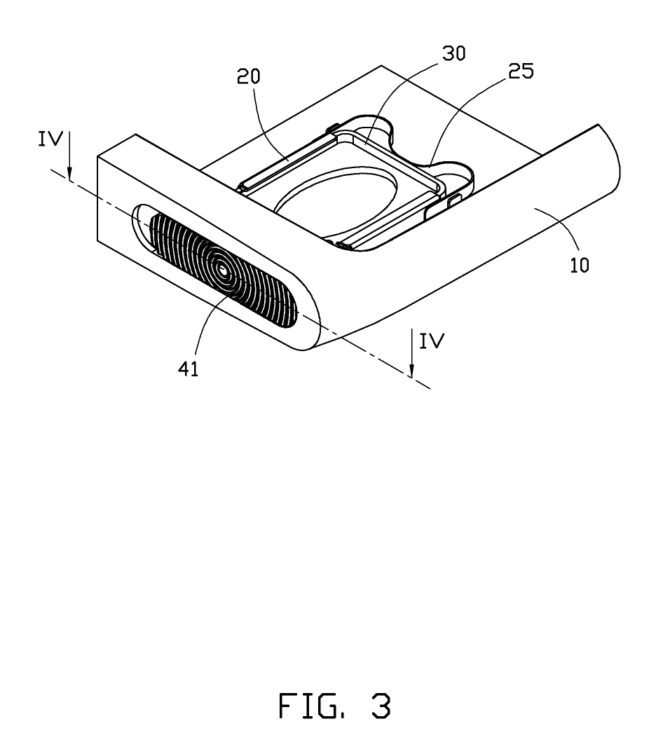

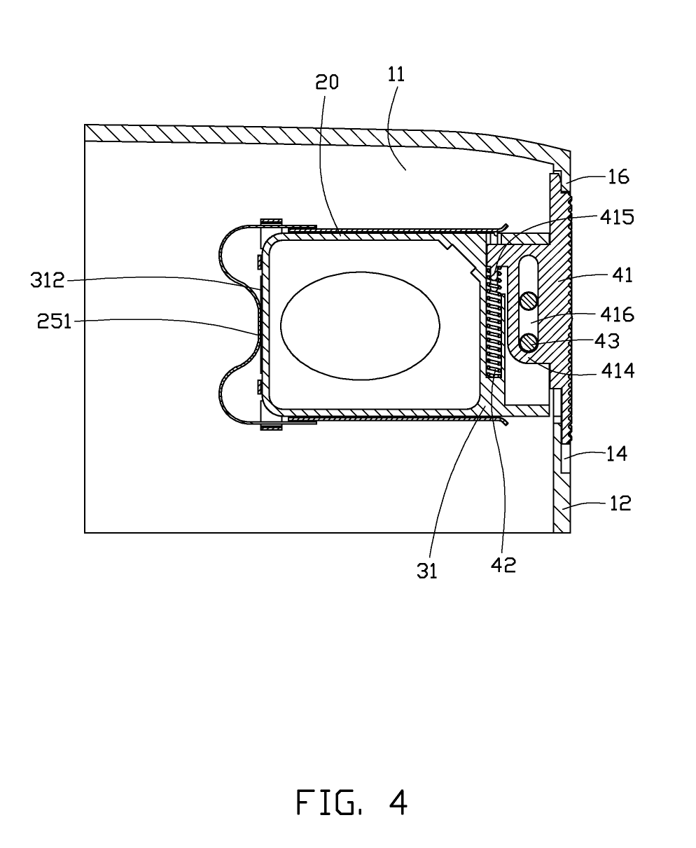

During assembly, referring to FIGS. 3-4, the receiving frame 20 is mounted on the main body 11 of the housing 10. The entrance 211 of the receiving frame 20 is aligned with the first hole 14 and the second hole 15. Then, the elastic member 42 is received in the cutout 332 of the tray 30. The extending block 414 of the protective cover 40 is inserted into the slot 331 of the tray 30, and the post 415 is aligned with the cutout 332. The elastic member 42 is partially fitted around the post 415 to allow the elastic member 42 to be positioned between the tray 30 and the protective cover 40. The fastener members 43 are inserted into the fastener holes 333 and the guiding groove 416, and can be any suitable fastener engageable in the fastener holes 333 of the tray 30 such as through friction fit or threaded engagement. Accordingly, the protective cover 40 is slidably assembled to the tray 30, but cannot separate from the tray 30. After that, the protective cover 40 with the tray 30 is inserted inside of the housing 10 through the first hole 14 and the second hole 15. The tray 30 is slidably received in and retained by the flanges 22. The first plate portion 41 and the second plate portion 44 are pushed to be respectively received in the first hole 14 and the second hole 15. The protective cover 40 is slid relative to the tray 30 until the stopper portion 16 blocks the second plate portion 44. Accordingly, the protective cover 40 is locked on the housing 10. At that time, the distal end 312 of the tray 30 presses into the ejecting member 25 so that the ejecting member 25 is resiliently deformed. Thus, the assembly process of the chip card holder 100 is finished.

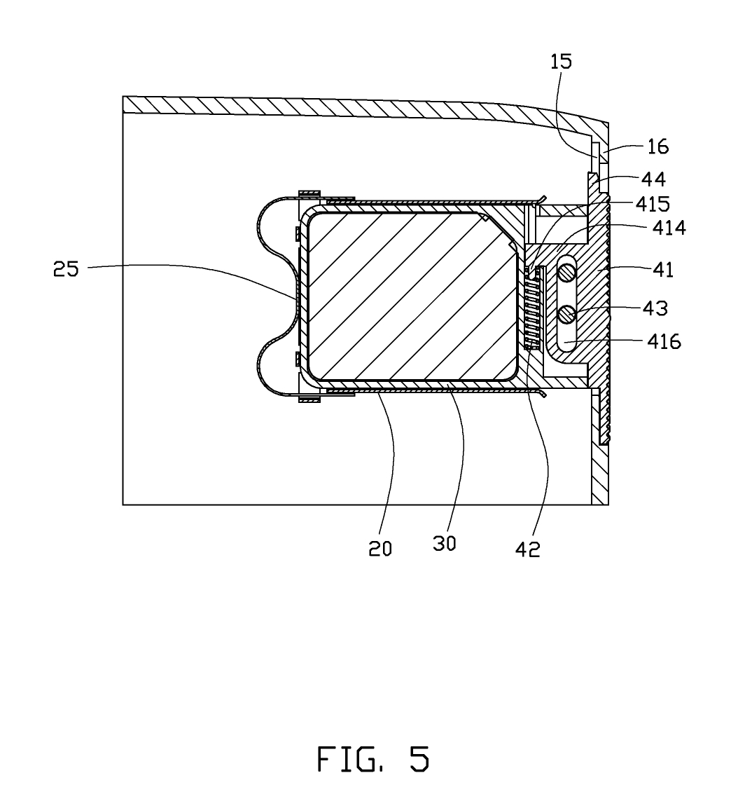

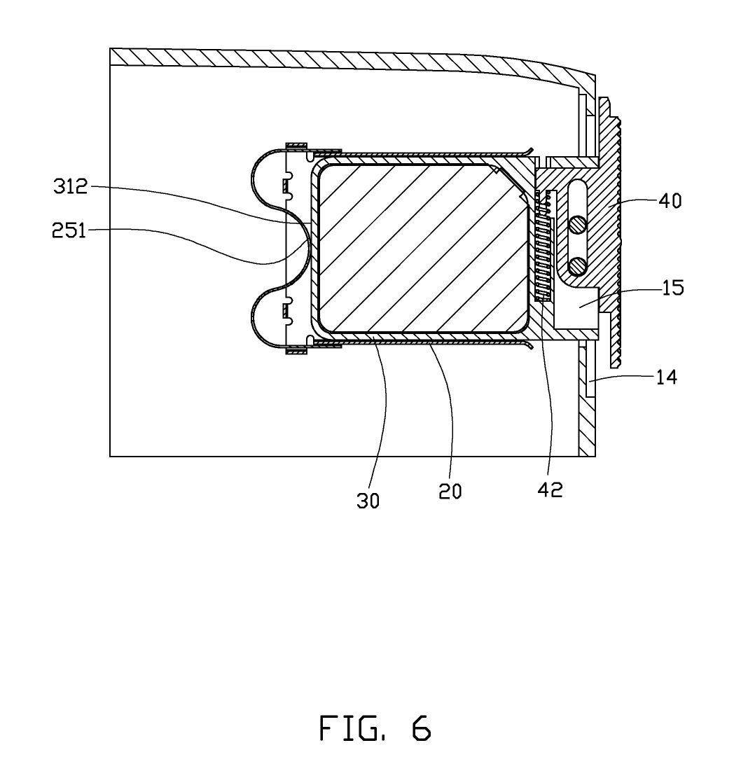

To remove the chip card, referring to FIG. 5 and 6, the protective cover 40 is slid along the first hole 14 and the second hole 15. The extending block 414 slides in the slot 331 relative to the fastener members 43, and compresses the elastic member 42 until the second plate 44 is not blocked by the stepped portion 16 to unlock the protective cover 40 relative to the housing 10. The tray 30 is pushed out by the ejecting member 25 exerting a force on the tray 30 to move the protective cover 40 out of the first hole 14 and the second hole 15. The tray 30 is further pulled to extend from the first hole 14 and the second hole 15. Accordingly, the tray 30 is slid out of the receiving frame 20. Thus, the chip card can then be easily removed from the tray 30.

As described above, the exemplary embodiment provides a chip card holder for portable electronic devices, such as mobile phones. The chip card holder can be easily opened, and the protective cover 40 can effectively hide and protect the tray 30.

Although numerous characteristics and advantages of the exemplary disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A chip card holder comprising:
a housing defining a hole;
a receiving frame mounted on the housing;
an ejecting member positioned at one end of the receiving frame;
a tray slidably received in the receiving frame and abutted by the ejecting member;
an elastic member positioned between the tray and the protective cover; and
a protective cover slidably connected to the tray and covering the hole;
wherein after the protective cover is slid along the housing and is unlocked from the housing, the ejecting member ejects the tray from the housing.

2. The chip card holder of claim 1, wherein the receiving frame includes a frame body and two opposite flanges, thereby cooperatively defining a receiving cavity, an entrance is defined at one end of the frame body to allow the tray to be inserted into the receiving cavity therethrough.

3. The chip card holder of claim 1, wherein the ejecting member is made of elastic sheet, and includes an elastic body and two mounting portions, each mounting portions is located at one end of the elastic body, and is configured for being mounted on the receiving frame.

4. The chip card holder of claim 3, wherein the elastic body is substantially W-shaped configured for providing an elastic force for ejecting the tray from the receiving frame.

5. The chip card holder of claim 1, wherein the tray includes a mounting portion, the mounting portion defines a slot, the protective cover includes an extending block slidably received in the slot.

6. The chip card holder of claim 5, further comprising at least one fastener member, wherein the mounting portion defines at least one fastener hole, the extending block defines a guiding groove, the at least one fastener hole is aligned with the guiding groove, the at least one fastener member is latched in the at least one fastener member, and is slidably received in the guiding groove.

7. The chip card holder of claim 5, wherein a post projects from one end of the extending block, the mounting portion defines a cutout, the post is aligned with the cutout, the elastic member is partially fitted around the post.

8. A portable electronic device, comprising:
a housing defining a first hole and a second hole;
a receiving frame mounted on the housing;
an ejecting member positioned at one end of the receiving frame;
a tray slidably received in the receiving frame and abutted by the ejecting member;
an elastic member positioned between the tray and the protective cover; and
a protective cover slidably connected to the tray, the protective cover including a first plate portion and a second plate portion respectively engaging in the first hole and the second hole;
wherein the protective cover is slid along the housing and is unlocked from the housing, the ejecting member ejects the tray from the housing.

9. The portable electronic device of claim 8, wherein the tray includes a mounting portion, the mounting portion defines a slot, the protective cover includes an extending block, the extending block perpendicularly extends from the second plate portion, and is slidably received in the slot.

10. The portable electronic device of claim 9, further comprising at least one fastener member, wherein the mounting portion defines at least one fastener hole, the extending block defines a guiding groove, the at least one fastener hole is aligned with the guiding groove, the at least one fastener member is latched in the at least one fastener member, and is slidably received in the guiding groove.

11. The portable electronic device of claim 9, wherein a post projects from one end of the extending block, the mounting portion defines a cutout, the post is aligned with the cutout, the elastic member is partially fitted around the post.
